(19) United States
(12) Patent Application Publication
(10) Pub. No.: US 2025/0183865 A1
(43) Pub. Date: Jun. 5, 2025

(54) EQUALIZER AND METHOD OF OPERATION THEREOF

(71) Applicant: INDIAN INSTITUTE OF TECHNOLOGY ROPAR, Punjab (IN)

(72) Inventors: Puneet SINGH, Punjab (IN); Rahul WALIA, Punjab (IN); Rajasekhar NAGULAPALLI, Oxford (GB); Mahendra SAKARE, Punjab (IN)

(73) Assignee: INDIAN INSTITUTE OF TECHNOLOGY ROPAR, Punjab (IN)

(21) Appl. No.: 18/615,959

(22) Filed: Mar. 25, 2024

(30) Foreign Application Priority Data
Dec. 1, 2023 (IN) 202311081865

(51) Int. Cl. H03G 5/16; H03F 3/45; H04L 25/03

(52) U.S. Cl. CPC H03G 5/165; H03F 3/45475; H03F 2200/451; H03G 2201/103; H04L 25/03057

(57) ABSTRACT

A continuous time linear equalizer (CTLE) circuit (100) comprises a main stage (101) and an auxiliary stage (102). The main stage (101) comprises a first differential amplifier stage circuit having a differential pair of transistors (M₁, M₂), configured to operate independently to amplify signals in a low-frequency range and change a DC gain of the main stage (101). An auxiliary stage (102) comprising a differential amplifier stage circuit having a second differential pair of transistors (M₃, M₄), configured to operate independently to change AC gain peaking of the auxiliary stage (102), wherein the main stage (101) is electrically coupled to the auxiliary stage (102) via a pair of coupling capacitors, and the change in the DC gain of the main stage (101) has no effect on the change in the AC gain peaking of the auxiliary stage (102), or vice versa.

### CROSS-REFERENCE TO RELATED APPLICATIONS AND PRIORITY

The present application claims benefit from Indian Patent Application No.: 202311081865 filed on 1 Dec. 2023 entirety of which is hereby incorporated by reference.

### TECHNICAL FIELD

The present subject matter described herein, in general, relates to an equalizer circuit. Particularly, the present subject matter relates to a continuous time linear equalizer (CTLE) circuit used for wireline applications.

### BACKGROUND OF THE INVENTION

Over the past few decades, there has been a significant threefold increase in the utilization of communication networks. In the early days of the Internet, users predominantly engaged in activities such as email communication and participation in bulletin boards. Their internet usage primarily revolved around text-based information retrieval, and the data being transmitted was relatively modest in size.

The use of communication networks has tripled in the last few decades. Early Internet users mostly used email bulletin boards and primarily used the Internet for text-based, informative web surfing, with relatively small amounts of data being transferred. In order to transfer multimedia files such as photos, videos, music, and other files, modern Internet and mobile applications require a massive amount of bandwidth. For instance, a social network like Facebook processes over 500 TB of data daily. The current data communication systems must be enhanced to meet the increasing data and data transfer demands. CTLE is frequently used in communication applications to enhance signal integrity. Conventional CTLE devices have been available in the past in a variety of forms, but sadly, they have not been sufficient. Therefore, having updated or new CTLE devices is desirable.

Within the realm of communication applications, CTLE plays a vital role in enhancing signal integrity. An important consideration in designing RC degenerated equalizers is the inherent trade-off between achieving a high DC gain and providing a substantial gain boost at higher frequencies. This trade-off stems from the positioning of the zero in the high-pass RC network, a decision that significantly influences the gain response's characteristics, particularly its DC gain. This trade-off becomes especially pertinent when the subsequent circuit in the signal chain is a sampler. Samplers often necessitate a specific differential input swing to function optimally, which adds complexity to the design process. One common approach to increasing the gain boost while maintaining a consistent DC gain is to augment the tail current. However, this strategy has its limitations. Increasing the tail current inevitably leads to a reduction in the output common mode voltage. In certain scenarios, this diminished common mode voltage may not be acceptable, introducing constraints on the overall system's performance. Moreover, there is an upper threshold to how much the tail current can be increased since excessively low output common mode voltages can disrupt the proper functioning of the subsequent stages in the signal processing chain.

To address these challenges, an approach has been proposed in the form of a gain-peaking CTLE circuit. This innovative solution eliminates the reliance on tail current adjustments and introduces a fresh technique for achieving the desired results without compromising the circuit's overall performance. This breakthrough holds the promise of overcoming the limitations inherent in conventional CTLE designs, offering a more versatile and effective means of achieving gain peaking while simultaneously maintaining a stable DC gain.

Hence to overcome the aforesaid drawbacks an efficient continuous time linear equalizer (CTLE) circuit is required.

### OBJECTS OF THE INVENTION

Main object of the present disclosure is to provide a continuous time linear equalizer (CTLE) circuit to provide a differential amplifier configuration that harnesses the interaction between the Main and auxiliary stages to achieve frequency-dependent gain control without sacrificing performance at lower frequencies.

Another object of the present disclosure is to provide the continuous time linear equalizer (CTLE) to further provide the main stage to operate independently to amplify signals in a low-frequency range and change the DC gain of the main stage.

Yet another object of the present disclosure is to provide the CTLE circuit to provide the auxiliary stage to operate independently to change the AC gain peaking of the auxiliary stage.

### SUMMARY OF THE INVENTION

Before the present system is described, it is to be understood that this application is not limited to the particular machine, device, or system, as there can be multiple possible embodiments that are not expressly illustrated in the present disclosures. It is also to be understood that the terminology used in the description is for the purpose of describing the particular versions or embodiments only, and is not intended to limit the scope of the present application. This summary is provided to introduce aspects related to continuous time linear equalizer (CTLE), and the aspects are further elaborated below in the detailed description. This summary is not intended to identify essential features of the proposed subject matter nor is it intended for use in determining or limiting the scope of the proposed subject matter.

An equalizer circuit (100) comprising a main stage (101) further comprising a first differential amplifier stage circuit having a first differential pair of transistors (M₁, M₂), wherein source terminals of the transistors (M₁, M₂) are linked to a drain of a tail current transistor (M_{b1}), configured to operate independently to amplify signals in a low-frequency range and change a DC gain of the main stage (101). An auxiliary stage (102) comprising a first differential amplifier stage circuit having a second differential pair of transistors (M₃, M₄), wherein source terminals of the transistors (M₃, M₄), are linked to a drain of another tail current transistor (M_{b2}), configured to operate independently to change AC gain peaking of the auxiliary stage (102); wherein the main stage (101) is electrically coupled to the auxiliary stage (102) via a pair of coupling capacitors (109) (110) of predefined value, the pair of coupling capacitors comprises a first coupling capacitor (C) (109) coupled between a drain terminal of the main stage transistor M₁ and a drain terminal of the auxiliary stage (102) transistor M₃. A second coupling capacitor (C) (110) coupled between a drain terminal of the main stage (101) transistor M₂ and a drain terminal of the auxiliary stage (102) transistor M₄, wherein the change in the DC gain of the main stage (101) has no effect on the change in the AC gain peaking of the auxiliary stage (102), or vice versa.

In an embodiment, the equalizer's DC gain is altered by manipulating or fine-tuning a tail current of the main stage (101) current transistor (M_{b1}), and an AC gain of the equalizer is finely tuned by adjusting a tail current of the auxiliary stage (102) tail current transistor (M_{b2}).

In an embodiment, the predefined value of the pair of capacitors is less than 150×10⁻¹⁵ farads.

In an embodiment, the power supply voltage V_{dd} is provided to the equalizer and is connected to the first differential pair of transistors (M₁, M₂) and second differential pair of transistors (M₃, M₄), via a first load resistor R₁ (111), a second load resistor R₂ (112), a first load capacitor C₁ (113), and a second load capacitor C₂ (114).

In an embodiment, the first load capacitor C₁ (113), and the second load capacitor C₂ (114), are connected in series with the first load resistor R₁ (111) and second load resistor R₂ (112), respectively.

In an embodiment, the circuit's overall gain is configured to increase or decrease at high frequencies based on a fine-tuning of relative biasing of the main (101) and auxiliary stages (102), load resistors values, and the coupling capacitors (C) values.

In an embodiment, the first load capacitor C₁ (113), the second load capacitor C₂ (114), the first load resistor R₁ (111) and second load resistor R₂ (112), and the first coupling capacitor (C) (109) and the second coupling capacitor (C) (110) are matching in values.

In an embodiment, the transistors of the main (101) and auxiliary stages (102) comprises the NMOS transistor.

In an embodiment, the wireline communication system comprises an equalizer circuit (100).

In an embodiment, the method of operation of an equalizer comprising a method of operation of equalizer comprising receiving an analog signal, applying a variable first DC gain to the analog signal at a pre-determined frequency while attenuating the analog signals at frequencies in a low frequency range below the frequency, wherein the first DC gain is provided by a main stage (101) of the equalizer; and applying a variable AC Peaking gain to the analog signal at the pre-determined frequency in the low frequency range, wherein the AC Peaking gain is provided by a an auxiliary stage (102) of the equalizer; wherein the variation in the DC gain of the main stage (101) has no effect on the variation in the AC gain peaking of the auxiliary stage (102), or vice versa.

In an embodiment the pre-determined frequency is at least in the range of 1-12.5 GHZ

In yet another embodiment the low frequency range is at least in the range of 100-500 KHz.

### BRIEF DESCRIPTION OF DRAWING

The foregoing summary, as well as the following detailed description of embodiments, is better understood when read in conjunction with the appended drawings. For the purpose of illustrating the disclosure, there is shown in the present document example constructions of the disclosure, however, the disclosure is not limited to the specific methods and device disclosed in the document and the drawing. The detailed description is described with reference to the following accompanying figures.

FIG. 1: illustrates the block diagram of wireline communication, in accordance with an embodiment of the present subject matter.

FIG. 2: illustrates the graphical AC response of channel loss (dB), in accordance with an embodiment of the present subject matter.

FIG. 3: illustrates the AC response of the channel convoluted with an equalizer response with less distorted output.

FIG. 4: illustrates the prior art consisting of a) a circuit diagram, and (b) a gain plot of the RC degenerated equalizer.

FIG. 5: illustrates the block diagram of the proposed CTLE comprising two stages (main and auxiliary) wherein the output of both circuits is coupled.

FIG. 6: illustrates the proposed exploded view of gain-peaking CTLE.

FIG. 7: illustrates the high-frequency equivalent model.

FIG. 8: illustrates the AC response for (a) change in DC gain while changing the tail current, and (b) change in DC gain while changing the tail current of the auxiliary stage (102).

FIG. 9: illustrates the Eye diagram of (a) 12.5 GHZ PRBS data after a 20-inch channel trace, (b) RC degenerated equalizer, and (c) Proposed CTLE. The data jitter (p-p) for the RC degenerated equalizer and the proposed CTLE are 41.39 ps and 24 ps, respectively. The eye width is 39.51 ps, 55.98 ps, and the eye-opening is 3.9 mV and 9.23 mV, respectively.

FIG. 10: illustrates the Eye diagram of (a) 8 GHz PRBS data after a 30-inch channel trace, (b) RC degenerated equalizer, and (c) Proposed CTLE. The data jitter (p-p) for the RC degenerated equalizer and the proposed CTLE are 65.76 ps and 34.7 ps, respectively. The eye width is 54.6 ps, 80.07 ps, and the eye-opening is 4.03 mV and 10.97 mV, respectively.

The figures depict various embodiments of the present disclosure for purposes of illustration only. One skilled in the art will readily recognize from the following discussion that alternative embodiments of the structures illustrated herein may be employed without departing from the principles of the disclosure described herein.

### DETAILED DESCRIPTION OF THE INVENTION

Some embodiments of this disclosure, illustrating all its features, will now be discussed in detail. The words “comprising”, “having”, and “including,” and other forms thereof, are intended to be equivalent in meaning and be open ended in that an item or items following any one of these words is not meant to be an exhaustive listing of such item or items, or meant to be limited to only the listed item or items. It must also be noted that as used herein and in the appended claims, the singular forms “a,” “an,” and “the” include plural references unless the context clearly dictates otherwise. Although any devices and methods similar or equivalent to those described herein can be used in the practice or testing of embodiments of the present disclosure, the exemplary, devices and methods are now described. The disclosed embodiments are merely exemplary of the disclosure, which may be embodied in various forms.

Various modifications to the embodiment will be readily apparent to those skilled in the art and the generic principles herein may be applied to other embodiments. However, one of ordinary skill in the art will readily recognize that the present disclosure is not intended to be limited to the embodiments illustrated, but is to be accorded the widest scope consistent with the principles and features described herein.

Following is a list of elements and reference numerals used to explain various embodiments of the present subject matter.

| Reference Numeral | Element Description |
|---|---|
| 100 | Equalizer circuit |
| 101 | Main stage |
| 102 | Auxiliary stage |
| 109 | First coupling capacitor (C) |
| 110 | Second coupling capacitor (C) |
| 111 | First load resistor R₁ |
| 112 | Second load resistor R₂ |
| 113 | First load capacitor C₁ |
| 114 | Second load capacitor C₂ |

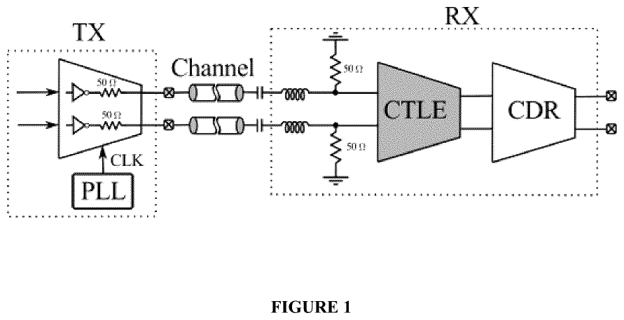

FIG. 1 illustrates a simplified block diagram of a continuous time linear equalizer (CTLE) within a communication system. Specifically, the CTLE module is implemented at the receiver (RX) side. Its primary function is to enhance the quality of incoming signals before they undergo further processing. Once signals are transmitted from the transmitter (TX) through the channel, the CTLE module equalizes these signals, as shown in FIG. 1. As an integral part of the analog front-end section of the communication device, the CTLE module operates to mitigate signal distortion and irregularities. After the CTLE module has effectively equalized the incoming signals, subsequent signal processing tasks come into play. These tasks may encompass functions such as Clock Data Recovery (CDR), Analog-to-Digital Conversion (ADC), and other requisite processes. The main objective of the CTLE module within this context is to ensure that the incoming data is adjusted and corrected to a form that is amenable to further processing. This is a fundamental step in maintaining the integrity of the communication system and enabling the accurate extraction of meaningful information from the received signals.

High-speed serial links (HSSL) serve as the fundamental components of reliable wired communication across a wide range of modern devices. These standards enable smooth data transfer and are considered fundamental to several widely adopted practices. Several examples of these standards are USB 3.1, HDMI 2.0, PCIe, SATA III, and Thunderbolt, all of which have been developed with the intention of fulfilling specific data transfers from one end to another. Table 1 summarizes the data rates linked to various widely adopted standards in modern technology. USB has experienced advancements in data transmission speeds, evolving from USB Gen 1.0 to USB Gen 4.0, which serves as a testament to the persistent pursuit of faster and more efficient communication interfaces in contemporary electronic products.

TABLE 1.1
Serial Link Data Rates

| Parameter | Value |
|---|---|
| SATA III | 6 Gbps |
| USB 3.1 | 10 Gbps |
| PCIe 4.0 | 16 GTps |
| HDMI 2.0 | 18 Gbps |
| Thunderbolt 3.0 | 40 Gbps |

The growing demand for high-bandwidth and robust wireline communication systems has become increasingly evident in today's technology. To meet this demand, one effective approach is to enhance the bandwidth of wireline communication by employing multiple parallel links. However, the use of parallel links introduces various challenges, including crosstalk, timing skew, a larger on-chip footprint, and elevated manufacturing costs. Fortunately, significant progress has been made in the realm of serial links, enabling the achievement of exceptionally high data rates while mitigating these challenges. Among the advancements in this field, high-bandwidth equalizers have emerged as a pivotal solution. These equalizers are typically implemented on both the transmitter and receiver sides of the communication system, serving to counteract the adverse effects of channel losses, inter-symbol interference (ISI), and jitter.

Two types of receiver equalizers are commonly employed within data communication systems: Continuous-Time Linear Equalizers (CTLE) and Decision Feedback Equalizers (DFE). These circuits play a crucial role in enhancing signal integrity and recovering data accurately. Moreover, many variations and design innovations in contemporary technology have surfaced, offering the dual benefits of achieving high data rates while maintaining high power efficiency. These advancements underscore the ongoing efforts to optimize wireline communication systems for the ever-increasing demands of modern data transfer requirements.

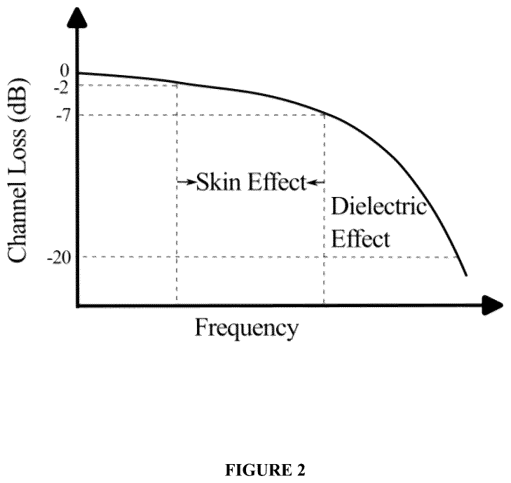

In an ideal scenario, the CTLE is designed to address the equalization of incoming signals across various frequencies and gain levels. Among its multifaceted functions, one role of the CTLE is to compensate for channel losses commonly encountered during data transmission. FIG. 2 illustrates a simplified graphical representation depicting channel loss. As evident in FIG. 2, channel loss is observed across a range of frequencies, encompassing both high- and low-frequency levels. Typically, serial communication channels experience channel loss due to two primary phenomena: the skin effect and dielectric effects.

$$Channel Loss ( dB ) = \frac{{R}_{skin}}{\sqrt{f}} + \frac{{K}_{Die}}{f} \qquad ( 1 )$$

Further, the skin effect predominantly manifests at lower frequency ranges, typically in the realm of a few megahertz (MHz). This phenomenon is characterized by a gradual attenuation of the signal as the frequency decreases. The loss incurred in the region dominated by the skin effect exhibits a relatively mild slope, typically in the range of 3-4 decibels per decade. Conversely, at higher frequency levels, the dielectric effect becomes increasingly prominent. This effect can extend up to the Nyquist Frequency and is marked by a more substantial loss in signal amplitude. As the frequency level rises, the dielectric effect's impact on channel loss becomes more pronounced, reaching a magnitude of approximately-20 decibels in FIG. 2. The CTLE is adept at addressing these frequency-dependent channel losses by selectively amplifying or attenuating different frequency components within the incoming signal. This equalization process ensures that the transmitted data can be effectively received and interpreted across the entire spectrum of frequencies, ultimately contributing to the reliability and fidelity of the communication system.

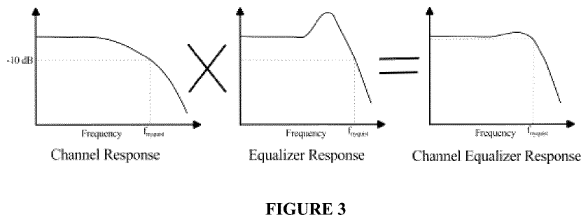

CTLE modules play a pivotal role in effectively mitigating the adverse effects of channel loss. To illustrate the efficacy of CTLE equalization, FIG. 3 illustrates the graphical representation of channel response having an impact of using an equalizer. The left graph in FIG. 3 provides insight into the channel response and the inherent presence of channel loss. Specifically, at the Nyquist frequency, denoted as F_{Nyquist}, there is a notable sharp drop in signal strength, registering at approximately 10 decibels (dB). The CTLE module is intelligently configured to counteract this channel loss. Moving to the middle graph, we observe the response of the equalizer, which essentially represents the CTLE module's contribution. This response curve appears nearly flat, with a distinctive peak occurring precisely at the Nyquist frequency. This peak is indicative of the CTLE's ability to boost signal strength where it is most needed. The rightmost graph, illustrating the equalized channel response, demonstrates the significant improvement achieved by the CTLE module. Here, the signal strength remains remarkably consistent, hovering around the −3 dB mark up to the Nyquist frequency, denoted as F_{nyquist}. The presence of channel loss, characterized by its nonlinearity, can have detrimental effects on data signals. Among these effects, frequency-dependent channel loss introduces a phenomenon known as inter-symbol interference (ISI), which can severely compromise the link margin, affecting data integrity. The CTLE module exhibits a high-pass characteristic up to the Nyquist frequency, closely mirroring the inverse characteristics of the channel itself. To effectively address loss due to the skin effect, CTLE modules are designed to provide equalization in the lower frequency range, typically in the realm of megahertz. Simultaneously, to compensate for loss attributed to the dielectric effect, CTLE circuits are equipped to offer equalization in the higher frequency range, often extending into gigahertz territory. Various CTLE module embodiments include a low-frequency pole-zero pair in the megahertz frequency range along with a modest gain of a few decibels (dB). These modules introduce a high-frequency zero, typically operating in the gigahertz frequency range, to tackle the loss stemming from dielectric effects. These intricately designed CTLE modules effectively counteract the multifaceted challenges posed by channel loss, ensuring robust and reliable data communication over high-speed serial links.

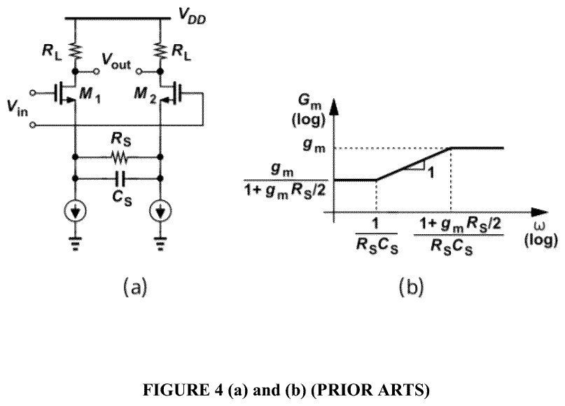

FIG. 4 illustrates a prior art showing a simplified diagram of a traditional CTLE with a typical gain plot vs. frequency response using a Bode approximation as shown in FIG. 4[6]. In this circuit, transistors M₁ and M₂ receive differential inputs. Source resistor Rs (111) and source capacitor Cₛ (115) are connected to the source terminals of transistors M₁ and M₂. These two components, Rₛ and Cₛ, are configured in parallel, which is known as source degeneration. The process of source degeneration plays a crucial role in the functioning of the circuit.

$${W}_{2} = \frac{1}{{R}_{S} {C}_{S}} \qquad ( 2 )$$

$${W}_{p 1} = \frac{1}{{R}_{L} {C}_{L}} \qquad ( 3 )$$

$${A}_{D C} = \frac{{g}_{m 1} {R}_{L}}{1 + \frac{{g}_{m 1} {R}_{S}}{2}} \qquad ( 4 )$$

where A_{DC} is DC gain, W_{Z} represents the zero position, and Wₚ₁ is the pole location.

The main objective of source degeneration is to induce peaking in the frequency response through the utilization of a high-pass RC network. This network allows for the adjustment of the zero's location by means of programmable resistors or capacitors. The utilization of a simplified high-frequency model results in the derivation of equations that effectively characterize the operational characteristics of the degraded differential pair. Nevertheless, it is crucial to acknowledge that there exists a trade-off between the direct current (DC) gain and the extent of gain amplification at higher frequencies within this particular circuit. The placement of the zero within the high-pass RC network is a determining factor in the presence or absence of gain peaking in the response, consequently influencing the direct current (DC) gain. The aforementioned trade-off might present a significant issue, particularly in cases when the succeeding circuit is a sampler, as it frequently necessitates a precise differential input swing for proper operation. One potential method for enhancing the gain boost factor while preserving a consistent DC gain is to augment the tail current. Nevertheless, this strategy is not without its constraints. In certain cases, the reduction of the output common mode voltage may not be deemed acceptable as a consequence of increasing the tail current.

Furthermore, it is important to note that there exists a maximum threshold for increasing the tail current. This is due to the fact that extremely low output common mode voltages can result in the inappropriate operation of the subsequent stage. The subsequent section offers a gain-peaking circuit that effectively eliminates the reliance on tail current and introduces a novel approach to attain the desired outcomes while maintaining the circuit's overall performance integrity. The proposed novel methodology offers potential solutions to address the constraints associated with traditional CTLE designs, offering a more adaptable and efficient strategy to achieve gain peaking while simultaneously preserving a consistent DC gain.

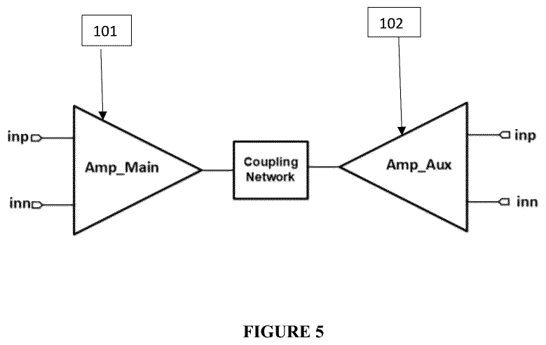

FIG. 5 illustrates the block diagram of the proposed CTLE. The CTLE comprises the integration of two separate differential stages that are joined through a coupling network. The complex arrangement of components significantly influences the operational capabilities and efficiency of the CTLE. The CTLE has an essential role in high-speed communication systems, specifically in the reduction of signal distortions and enhancement of signal integrity. The system functions in a continuous manner, effectively modifying the amplitude and phase of incoming signals in order to counterbalance any losses and distortions that may arise throughout the process of transmission. The inclusion of two distinct differential stages in the block diagram is a significant decision made throughout the design process. Every stage comprises electronic circuits that are responsible for the differential processing of incoming signals. This implies that these circuits function by operating on the voltage disparity between two input terminals. The utilization of this differential operation serves to improve the rejection of common-mode noise and augment the capability of the CTLE in delivering precise equalization. Furthermore, the coupling network interconnects these differential stages. This network serves as a bridge between the two stages, facilitating the transfer of signals while maintaining the desired impedance matching and signal integrity. The specific design and parameters of the coupling network are critical factors in achieving optimal equalization performance.

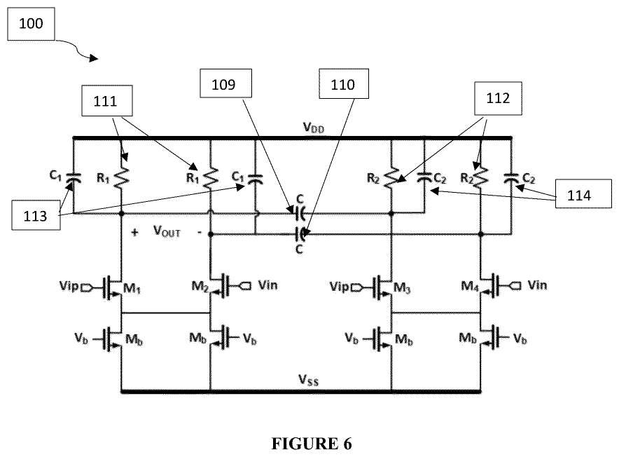

FIG. 6 illustrates the schematic of the proposed continuous time linear equalizer (CTLE) circuit (100), comprising two distinct differential amplifier stages the Main (101) and the auxiliary stages (102). These two stages are interconnected through the utilization of two capacitors (C coupling) (109) (110). In the Main stage, the differential inputs are achieved through transistors M1 and M2. The source terminals of transistors M1 and M2 are linked to the drain of the tail current transistor M3. Similarly, differential inputs are taken in the auxiliary stage (102) through transistors M3 and M4. Just as in the Main stage, the source terminals of transistors M3 and M4 are connected to the drain of another tail-current transistor, Mb. At lower frequencies, the two capacitors exhibit very high impedance characteristics. In this regime, the primary amplification within the circuit is a result of the tail current provided by the Main stage. Essentially, the Main stage operates independently to amplify signals in the low-frequency range. However, an exciting phenomenon comes into play as we transition to higher frequencies. The capacitors (109) (110) connecting the two stages start to come into effect. At these higher frequencies, the capacitors (109) (110) essentially couple the two output nodes of the Main (101) and auxiliary stages (102). The extent of this coupling and its impact on the overall gain depends on the specific bias conditions of both stages. This behavior leads to a dynamic response in which the gain of the circuit can increase or decrease at high frequencies based on the relative biasing of the Main (101) and auxiliary stages (102). This dynamic interaction between the two stages allows for a versatile and frequency-dependent gain adjustment, making the circuit suitable for a wide range of applications where precise control over signal amplification across frequency bands is required.

The main stage (101) is electrically coupled to the auxiliary stage (102) via a pair of coupling capacitors of predefined value, the pair of coupling capacitors comprises a first coupling capacitor (C) (109) coupled between a drain terminal of the main stage (101) transistor M₁ and a drain terminal of the auxiliary stage (102) transistor M₃. A second coupling capacitor (C) (110) coupled between a drain terminal of the main stage (101) transistor M₂ and a drain terminal of the auxiliary stage (102) transistor M₄, wherein the change in the DC gain of the main stage (101) has no effect on the change in the AC gain peaking of the auxiliary stage (102), or vice versa. The power supply voltage V_{dd} is provided to the equalizer and is connected to the first differential pair of transistors (M₁, M₂) and second differential pair of transistors (M₃, M₄), via a first load resistor R₁ (111), a second load resistor R₂ (112), a first load capacitor C₁ (113), and a second load capacitor C₂ (114).

In an embodiment, the first load capacitor C₁ (113), and the second load capacitor C₂ (114), are connected in series with the first load resistor R₁ (111) and second load resistor R₂ (112), respectively.

The main stage (101) is configured to operate independently to amplify signals in a low-frequency range and change the DC gain of the main stage (101) and the auxiliary stage (102) is configured to operate independently to change the AC gain peaking of the auxiliary stage (102).

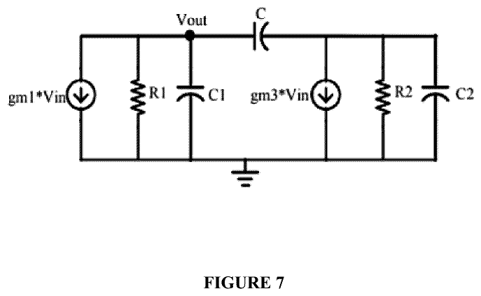

FIG. 7 illustrates the high-frequency equivalent model of the schematic, which provides insights into the circuit's behavior. Given is the transfer function (H(s)) of the small signal model.

$$H ( s ) = \frac{K ( s + {W}_{2} )}{{S}^{2} + \frac{{ω}_{0}}{Q} s + {ω}_{0}^{2}} \qquad ( 5 )$$

$${A}_{D C} = - {g}_{m 1} {R}_{L} \qquad ( 6 )$$

$${W}_{Z} = \frac{1}{{R}_{2} C ( 1 + \frac{{C}_{2}}{C} + \frac{{g}_{m 3}}{{g}_{m 1}} )} \qquad ( 7 )$$

$${W}_{0} = \frac{1}{\sqrt{{R}_{1} {R}_{2} ( {C}_{1} {C}_{2} + {CC}_{1} + {CC}_{2} )}} \qquad ( 8 )$$

$$Q = \frac{{R}_{1} {R}_{2} {ω}_{0}}{{R}_{2} ( C + {C}_{2} ) + {R}_{1} ( C + {C}_{1} )} \qquad ( 9 )$$

$${G}_{peak} = - ( {g}_{m 1} + {G}_{m 3} ) \frac{{R}_{1} {R}_{2}}{{R}_{1} + {R}_{2}} \qquad ( 10 )$$

Further, the ADC is the DC gain, WZ is the zero location, WO is the bandwidth, Q is the quality factor, and Gpeak is the maximum high-frequency peaking.

The adjustability of the bias conditions for the two differential stages (gm1, gm3), the characteristics of the resistor loads, and the properties of the coupling capacitors (109) (110) are crucial factors that contribute to the functionality of this circuit. By making meticulous modifications, it becomes feasible to attain an alternating current (AC) gain that exceeds the direct current (DC) gain. This, in return, contributes to gain peaking at higher frequencies.

The significance of equation (5) lies in its representation of the greatest achievable gain. However, the extent of peaking encountered by the circuit is contingent upon the specific positions of its zeroes and poles. In the subsequent sections, the gain response of the circuit can be precisely adjusted to fulfill certain criteria by the manipulation of different parameters.

Bias Conditions (gm1, gm3): The initial stage in customizing the circuit's response involves modifying the bias conditions of the differential stages, specifically gm1 and gm3. The manipulation of the trans-conductance values of these stages is a crucial factor that can exert a substantial influence on both the overall gain and frequency response.

Resistor Loads: A further essential aspect to take into account is the selection and arrangement of resistor loads inside the circuit. The resistors' values and their interconnections have the potential to impact both the DC and AC amplification, as well as the frequency response characteristics of the circuit.

Coupling Capacitors: The coupling capacitors play a role in defining the circuit's behavior at different frequencies. Their capacitance values and placement affect how signals are passed through the circuit, particularly with respect to low-frequency and high-frequency components.

By judiciously adjusting these parameters, it becomes possible to craft a tailored gain response that aligns with specific design goals. The flexibility of the circuit's parameters allows for precise tuning to achieve those goals, whether they are to increase gain at specific frequencies, widen the bandwidth, or achieve other desired characteristics. The intricate interplay of these components, which determines the actual extent of gain peaking, is significant and emphasizes the need for a methodical and knowledgeable approach to circuit design.

Further, the circuit's gain response can be adjusted to achieve desired characteristics by manipulating various parameters:

Zero Placement: The location of the zero in the circuit's transfer function is closely tied to the product of two vital elements: the auxiliary stage (102) load resistor (R₂) (112) and the coupling capacitor (C) (109) (110). It's important to note that the zero is inversely proportional to this product, as given by equation (6). This relationship provides a practical means to place the zero at a specific frequency of interest. By strategically modifying either the coupling capacitor (109) (110) or the auxiliary stage (102) load resistor, we can precisely control the position of this zero. However, a word of caution: when adjusting load resistor R₂ (112), it's advisable to make fine-tuned changes. Excessive alterations to load resistor R₂ (112) can impact the bias conditions of the auxiliary stage (102), potentially causing it to enter the cut-off region, which is undesirable.

Boosting or Gain Peaking: As per equation (5), it's evident that the DC gain of the circuit can be altered by manipulating the main stage (101) tail current. Simultaneously, the AC gain can be finely tuned by adjusting the auxiliary stage (102) tail current. This flexibility allows engineers to tailor the extent of gain peaking, effectively shaping the circuit's response from DC to AC in two distinct ways. In the first method, circuit vary the low-frequency gain by adjusting the main stage (101) tail current while keeping the auxiliary stage (102) current constant. This approach permits the tuning of the DC gain, thereby influencing the overall gain profile.

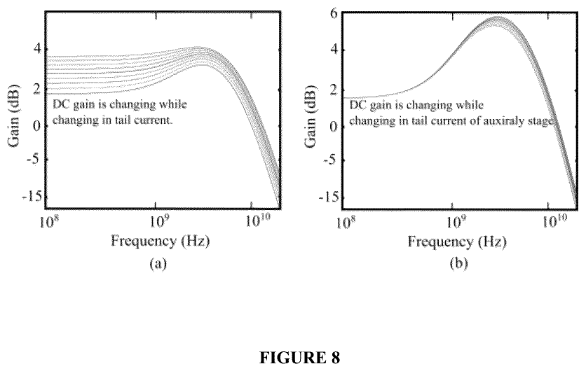

FIG. 8 (a) visually represents this method, showcasing how the DC gain changes as the main stage (101) tail current is modified in the RC degenerated equalizer. In the proposed CTLE, gain peaking is enabled while maintaining a constant DC gain shown in FIG. 8 (b). This is achieved by altering the auxiliary stage (102) tail current while keeping the main stage (101) tail current constant. Doing so allows us to fine-tune the AC gain exclusively, ensuring that the DC gain remains steady. This approach provides a means to control the amount of gain peaking, tailoring the circuit's response to meet specific design criteria and performance requirements.

TABLE 2
Comparison between RC degenerated equalizer and the proposed CTLE

| | Conventional | Proposed | Improvement |
|---|---|---|---|
| Parameter | CTLE | CTLE | (%) |
| Power(mW) | 0.947 | 1.203 | −21.28 |
| Gain (dB) | 1.778 | 1.993 | 10.78 |
| Gain Peaking (dB) | 3.36 | 5.47 | 38.57 |
| f_{3-dB} (GHz) | 10.17 | 13.66 | 25.54 |
| UGB (GHz) | 13.09 | 20.27 | 35.42 |

Table 2, represents a comparison between the RC degenerated equalizer and the proposed CTLE in terms of various performance metrics. The proposed CTLE exhibits superior characteristics in terms of gain peaking, bandwidth, and unity gain frequency when compared to the RC degenerated equalizer. The table shows that the proposed CTLE excels in both of these aspects compared to the RC degenerated equalizer, indicating its superior ability to handle a broader spectrum of signal frequencies and maintain signal integrity.

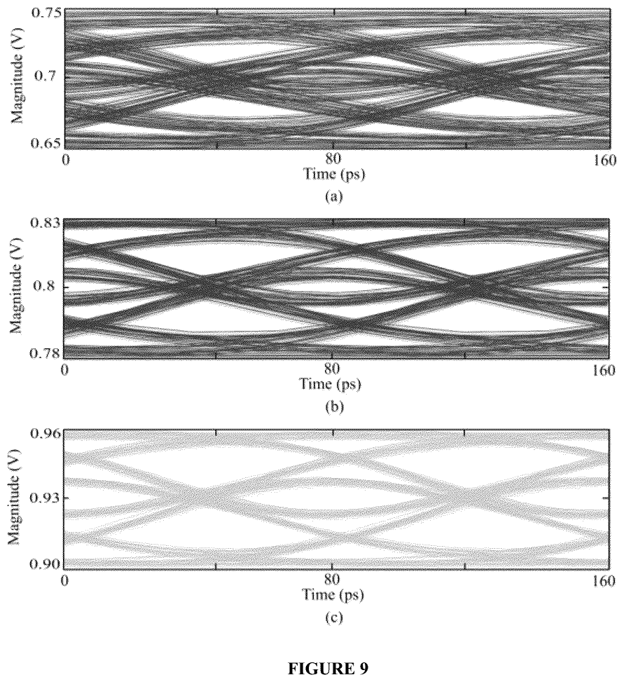

FIG. 9 illustrates the eye diagrams for the channel, the RC degenerated equalizer, and the proposed CTLE, all operating at a frequency of 12.5 GHz with a Pseudo-Random Binary Sequence (PRBS) data signal. The eye diagram is a visualization tool used in digital communication systems to assess the quality of a received signal. A well-defined and wide eye-opening in the diagram signifies a robust and clear signal, whereas a narrow or distorted eye-opening suggests signal degradation and potential data errors. From the eye diagrams presented in FIG. 8, it becomes evident that the data signal experiences a significant degradation after passing through the channel. However, this distortion is not adequately rectified by the RC degenerated equalizer. The eye-opening in the RC degenerated equalizer's diagram remains suboptimal, indicating that it struggles to effectively correct the signal distortions induced by the channel. Conversely, the proposed CTLE demonstrates a markedly improved performance. Its eye diagram exhibits a wider and more open eye-opening, indicative of better signal recovery and reduced distortion. This result underscores the effectiveness of the proposed CTLE in mitigating signal impairments, resulting in a higher-quality received signal.

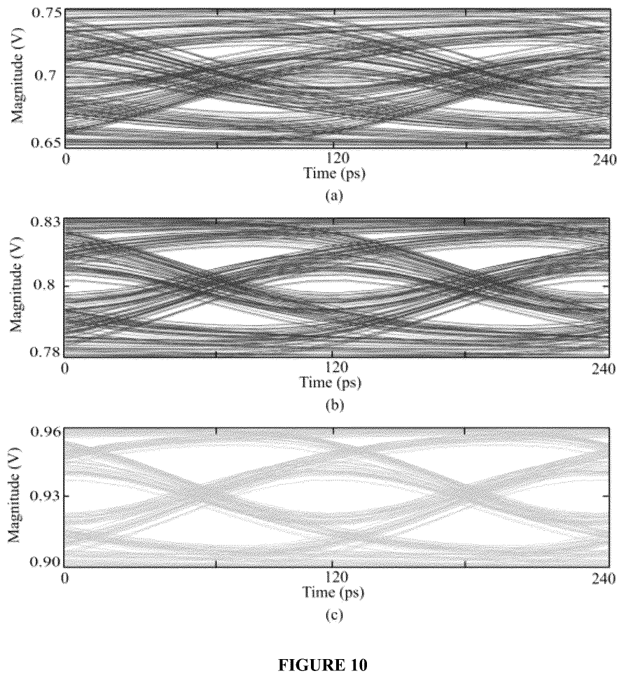

FIG. 10 illustrates the eye diagrams for the channel, the RC degenerated equalizer, and the proposed CTLE, all operating at a frequency of 12.5 GHz with a PRBS data signal. The proposed CTLE demonstrates a markedly improved performance. Its eye diagram exhibits a wider and more open eye-opening, indicative of better signal recovery and reduced distortion. This result underscores the effectiveness of the proposed CTLE in mitigating signal impairments, resulting in a higher-quality received signal.

In some embodiments, the DC gain response is precisely controlled over the circuit, to customize its behavior to match desired specifications. Whether it's placing zeroes at specific frequencies or adjusting gain peaking from DC to AC, these strategies empower designers to achieve the desired performance characteristics for their circuit designs.

In some embodiments, the CTLE designs, offer a more versatile and effective technique of achieving gain peaking while simultaneously maintaining a stable DC gain.

### EQUIVALENTS

With respect to the use of substantially any plural and/or singular terms herein, those having skill in the art can translate from the plural to the singular and/or from the singular to the plural as is appropriate to the context and/or application. The various singular/plural permutations may be expressly set forth herein for the sake of clarity.

It will be understood by those within the art that, in general, terms used herein, and especially in the appended claims (e.g., bodies of the appended claims) are generally intended as “open” terms (e.g., the term “including” should be interpreted as “including but not limited to,” the term “having” should be interpreted as “having at least,” the term “includes” should be interpreted as “includes but is not limited to,” etc.). It will be further understood by those within the art that if a specific number of an introduced claim recitation is intended, such an intent will be explicitly recited in the claim, and in the absence of such recitation no such intent is present.

Although implementations for the continuous time linear equalizer (CTLE) have been described in language specific to structural features and/or methods, it is to be understood that the appended claims are not necessarily limited to the specific features described. Rather, the specific features are disclosed as examples of implementation for the continuous time linear equalizer (CTLE).

1. An equalizer circuit (100) comprising:
a main stage (101) comprising a first differential amplifier stage circuit having a first differential pair of transistors (M₁, M₂), wherein source terminals of the transistors (M₁, M₂) are linked to a drain of a tail current transistor (M_{b1}), configured to operate independently to amplify signals in a low-frequency range and change a DC gain of the main stage (101);
an auxiliary stage (102) comprising a first differential amplifier stage circuit having a second differential pair of transistors (M₃, M₄), wherein source terminals of the transistors (M₃, M₄), are linked to a drain of another tail current transistor (M_{b2}), configured to operate independently to change AC gain peaking of the auxiliary stage (102);
wherein the main stage (101) is electrically coupled to the auxiliary stage (102) via a pair of coupling capacitors of predefined value, the pair of coupling capacitors comprises
a first coupling capacitor (C) (109) coupled between a drain terminal of the main stage transistor M₁ and a drain terminal of the auxiliary stage (102) transistor M₃;
a second coupling capacitor (C) (110) coupled between a drain terminal of the main stage (101) transistor M₂ and a drain terminal of the auxiliary stage (102) transistor M₄, and
wherein the change in the DC gain of the main stage (101) has no effect on the change in the AC gain peaking of the auxiliary stage (102), or vice versa.

2. The equalizer circuit (100) as claimed in claim 1, wherein the equalizer's DC gain is altered by manipulating or fine tuning a tail current of the main stage (101) current transistor (M_{b1}) and an AC gain of the equalizer is finely tuned by adjusting a tail current of the auxiliary stage (102) tail current transistor (M_{b2}).

3. The equalizer circuit (100) as claimed in claim 1, wherein the predefined value of the pair of capacitors is less than 150×10⁻¹⁵ farads.

4. The equalizer circuit (100) as claimed in claim 1, comprising a power supply voltage V_{dd} is provided to the equalizer and is connected to the first differential pair of transistors (M₁, M₂) and second differential pair of transistors (M₃, M₄), via a first load resistor R₁ (111), a second load resistor R₂ (112), a first load capacitor C₁ (113), and a second load capacitor C₂ (114).

5. The equalizer circuit (100) as claimed in claim 4, wherein the first load capacitor C₁ (113), and the second load capacitor C₂ (114), is connected in series with the first load resistor R₁ (111) and second load resistor R₂ (112), respectively.

6. The equalizer circuit (100) as claimed in claim 1, wherein the circuit overall gain is configured to increase or decrease at high frequencies based on a fine tuning of relative biasing of the main (101) and auxiliary stages (102), load resistors values, and the coupling capacitors (C) values.

7. The equalizer circuit (100) as claimed in claim 1, wherein the first load capacitor C₁ (113), the second load capacitor C₂ (114), the first load resistor R₁ (111) and second load resistor R₂ (112), and the first coupling capacitor (C) (109) and the second coupling capacitor (C) (110) are matching in values.

8. The equalizer circuit (100) as claimed in claim 1, wherein the transistors of the main (101) and auxiliary stages (102) comprises NMOS transistor.

9. A wireline communication system comprising an equalizer circuit (100) as claimed in claim 1.

10. A method of operation of equalizer comprising
receiving an analog signal,
applying a variable first DC gain to the analog signal at a pre-determined frequency while attenuating the analog signals at frequencies in a low frequency range below the frequency, wherein the first DC gain is provided by a main stage (101) of the equalizer; and
applying a variable AC Peaking gain to the analog signal at the pre-determined frequency in the low frequency range, wherein the AC Peaking gain is provided by a an auxiliary stage (102) of the equalizer;
wherein the variation in the DC gain of the main stage (101) has no effect on the variation in the AC gain peaking of the auxiliary stage (102), or vice versa.

11. The method as claimed in claim 10, wherein the pre-determined frequency is at least in the range of 1-12.5 GHz.

12. The method as claimed in claim 10, wherein the low frequency range is at least in the range of 100-500 KHz.
